(19) United States
(12) Patent Application Publication
(10) Pub. No.: US 2013/0334400 A1
(43) Pub. Date: Dec. 19, 2013

(54) METHOD OF MAKING LENS MODULES AND THE LENS MODULE

(71) Applicants: Ching-Shan Yang, Tainan (TW); Wu-Li Wang, Tainan (TW)

(72) Inventors: Ching-Shan Yang, Tainan (TW); Wu-Li Wang, Tainan (TW)

(73) Assignee: Global Microptics Company, Tainan (TW)

(21) Appl. No.: 13/526,220

(22) Filed: Jun. 18, 2012

(51) Int. Cl. B29D 11/00; H05K 3/22; H01L 27/146

(52) U.S. Cl. 250/208.1; 29/846; 264/2.7

(57) ABSTRACT

A method of making lens modules includes the following steps: Put a plurality of lens members between a first die and a second die, wherein the first die touches the substrate of each lens module, and the second die touches the lens of each lens module. Provide a housing material between the first die and the second die, and then solidify the housing material. Remove the first die and the second die to obtain a block; and Cut the block to obtain a plurality of lens modules.

### BACKGROUND OF THE INVENTION

1. Field of the Invention

The present invention relates generally to an optical device, and more particularly to an optical lens and a method of making the same.

2. Description of the Related Art

In recent days, consumer electronic devices, such as cell phone, laptop, tablet, and PDA, are equipped with lens module to catch images. These consumer electronic devices are made as smaller and lighter as possible for user to carry and operate in an easy way so that lens modules and the lens mounted in the lens module are asked smaller and lighter accordingly.

FIG. 1 shows a conventional lens module 60, including a substrate 62, an image sensor 64 on the substrate 62, a barrel 66 mounted on the substrate 62 to enclose the image sensor 64 therein, a lens 68 mounted in the barrel 66, and a housing 70 to enclose the above elements therein. The housing 70 is provided with an opening 72 above the lens 68. Fillers 74 are provided in a space between the housing 70 and the barrel 66 for anti-shake.

The conventional lens module 60 has several drawbacks, including: a weak structure, even there are the fillers 74 therein; high cost; large size, especially the housing 70 makes it thicker; and lens modules with different specifications need different housings.

### SUMMARY OF THE INVENTION

The primary objective of the present invention is to provide a lens module and a method of making such lens module, which the lens module has strong structure, small size, and low cost.

According to the objective of the present invention, a method of making lens modules includes the following steps:

Provide a plurality of lens members between a first die and a second die, wherein the lens member has a substrate having a conductor pattern, an image sensor on the substrate and electrically connected to the conductor pattern, a barrel mounted on the substrate, and a lens mounted in the barrel and above the image sensor; the first die has a plurality of positioning portions to respectively touch bottoms of the substrates of the lens members; the second die has a plurality of contacting portions to respectively touch at least a portion of each of the lenses; and a runner is formed between the lens members.

Provide a housing material between the first die and the second die to fill the runner with the housing material, and then curing the housing material, wherein the housing material embeds the lens members except the bottoms of the substrates touching the first die and the portions of the lenses touching the second die.

Remove the first die and the second die to obtain a block; and

Cutting the block to obtain a plurality of the lens module, wherein each of the lens module includes a housing formed by the housing material, and the lens member in the housing.

In an embodiment, the positioning portions of the first die are recesses on the first die, and the recesses are complementary to the substrates.

In an embodiment, the contacting portions of the second die are recesses on the second die, and the recesses are complementary to the portions of the lenses.

In an embodiment, the second die is flexible to be deformed by the lenses to form the contacting portions when the second die is put on the lens members and pressed.

In an embodiment, the contacting portions of the second die are posts on the second die to respectively touch the lenses by distal ends of the posts.

In an embodiment, the method of the present invention further includes the step of providing solder bumps on the bottoms of the substrates after the step of removing the first die and the second die.

In an embodiment, the method of the present invention further includes the step of providing solder balls on the bottoms of the substrates after the step of removing the first die and the second die.

In an embodiment, the housing material is selected from the group consisting of epoxy, natural rubber, and thermosetting plastic.

The present invention further provides a lens module, including a lens member including a substrate having a conductor pattern, an image sensor on the substrate and electrically connected to the conductor pattern, a barrel mounted on the substrate, and a lens mounted in the barrel and above the image sensor; and a housing embedding the lens member, wherein the housing has an opening on a top thereof to expose at least a portion of the lens of the lens member; and the housing has a cavity complementary to the lens member.

In an embodiment, the portion of the lens extends out of the housing through the opening.

In an embodiment, the lens is behind the opening, and touches a rear end of the opening.

In an embodiment, the substrate has a portion not covered by the housing, on which solder bumps are provided to electrically connect to the conductor pattern.

In an embodiment, the substrate has a portion not covered by the housing, on which solder balls are provided to electrically connect to the conductor pattern.

Therefore, the present invention is faster than the conventional method, and the lenses made by the method of the present invention are thinner and lighter than the lenses made by the conventional method.

### BRIEF DESCRIPTION OF THE DRAWINGS

FIG. 1 is a sectional view of the conventional lens module;

FIG. 2 is a sectional view of the lens member of a first preferred embodiment of the present invention;

FIG. 3 to FIG. 8 are sketch diagrams of making the lens module by the method of the first preferred embodiment of the present invention;

FIG. 9 is a sectional view of the lens module of the first preferred embodiment of the present invention;

FIG. 10 is a sketch diagram of the lens member and the second die of a second preferred embodiment of the present invention; and

FIG. 11 is a sectional view of the lens module of the second preferred embodiment of the present invention.

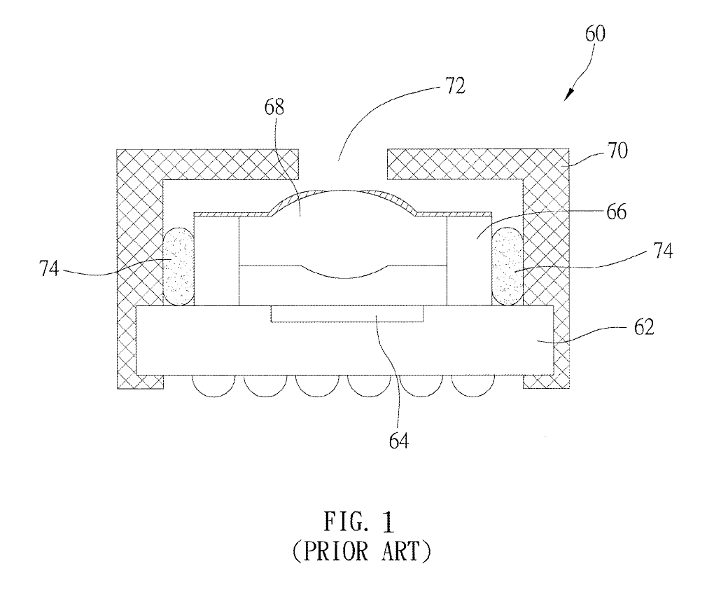

### DETAILED DESCRIPTION OF THE INVENTION

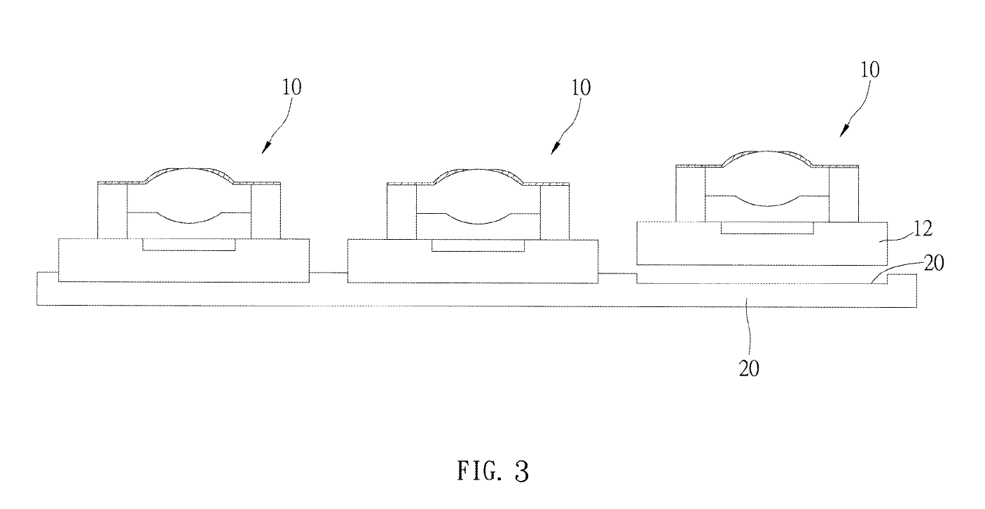

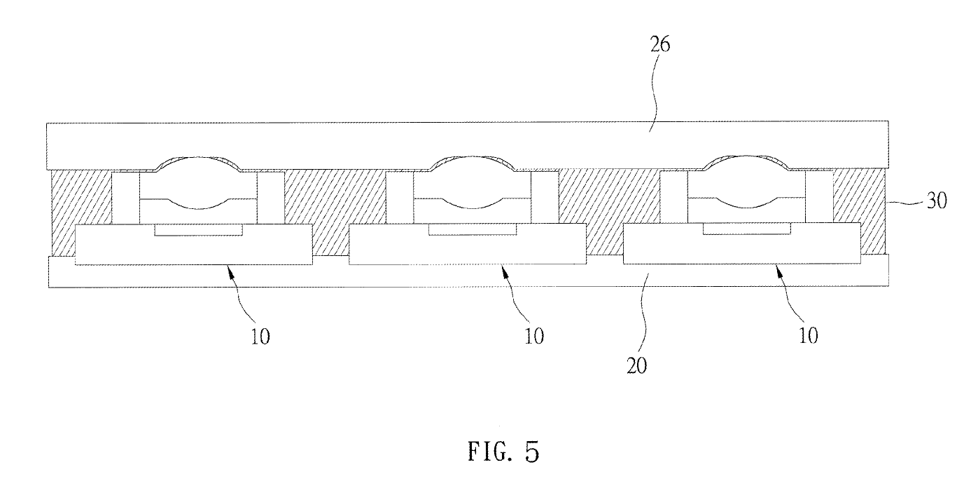

As shown in FIG. 3 to FIG. 8, a method of making lens modules of the first preferred embodiment of the present invention includes the following steps:

A. Put a plurality of lens members 10 on a first die 20:

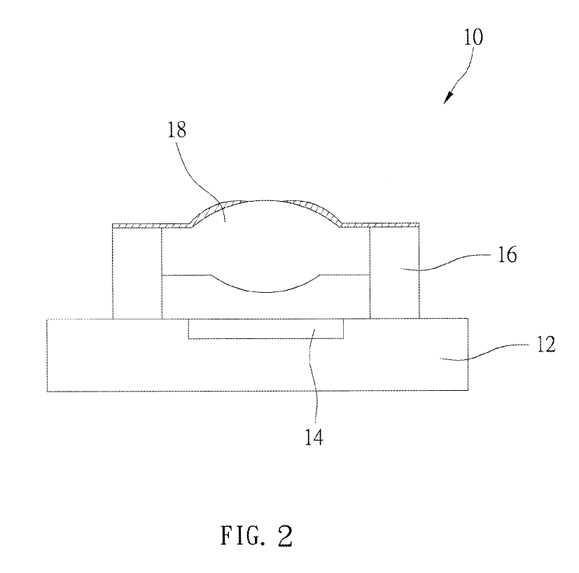

The lens members 10 are pre-made before performing the method of the present invention. Each lens member 10, as shown in FIG. 2, has a substrate 12 having a conductor pattern (not shown) thereon, an image sensor 14 provided on the substrate 12 and electrically connected to the conductor pattern, a barrel 16 mounted on the substrate 12, and a lens 18 mounted in the barrel 16 and above the image sensor 14. The first die 18 has a plurality of positioning portions 22 which are recesses fitted to the substrates 12 that the lens members 10 may be firmly put in each positioning portions 22, as shown in FIG. 3, to form a runner 24 between the lens members 10.

B. Put a second die 26 on the lens members 10:

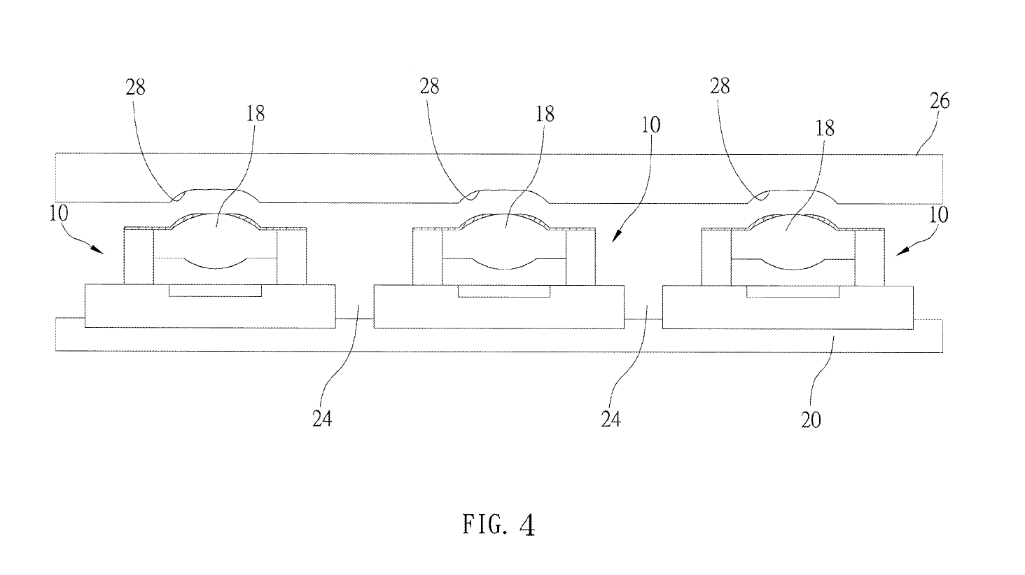

In the present embodiment, the second die 26 has the same size as the first die 20, and has a plurality of contacting portions 28 thereon to touch the lenses 18 of the lens members 10 respectively. In the present embodiment, the second die 26 is a rigid board with a plurality of recesses thereon, and the recesses are the contacting portions 28. The recesses are arranged in a matrix form, and the shapes of the recesses are complementary to at least a portion of the lenses 18 so that each lens 18 may has a portion received in the recess, and a sidewall of recess will tightly touch the lens 18, as shown in FIG. 4.

An alternate way is that the second die 26 is made of a flexible material, such as silicon rubber, therefore, the second die 26 will be partially deformed by the lenses 18 to tightly contact the lenses 18 when one puts the second die 26 on the lens members 10 and presses it.

A holder (not shown) will be applied to the first die 20 and the second die 26 to fix them for the following steps. The holder is a well-known skill, so we don't describe the detail here.

C. Provide a housing material 30 between the first die 10 and the second die 26, and then solidify it:

The housing material 30 may be epoxy, natural rubber, or thermosetting plastics, and epoxy is chosen in the present embodiment. Molten epoxy is poured into the runner 22 to fill a space between the first die 10 and the second die 26. At this stage, the epoxy will embed the lens members 10 except for the bottoms of the substrates 12 which tightly touch the positioning portions 22 of the first die 20, and the portions of the lenses 18 which tightly touch the contacting portions 28. Next, cool the epoxy 30 for curing.

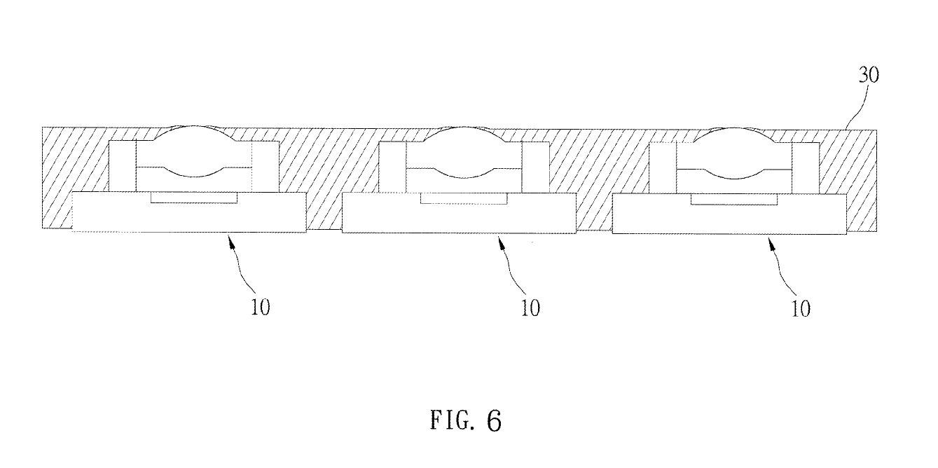

D. Remove the first die 10 and the second die 26, as shown in FIG. 6, to obtain a block of the solidified housing material 30. The lens members 10 are embedded in the block, and only the bottoms of the substrates 12 and the portions of the lenses 18 are exposed.

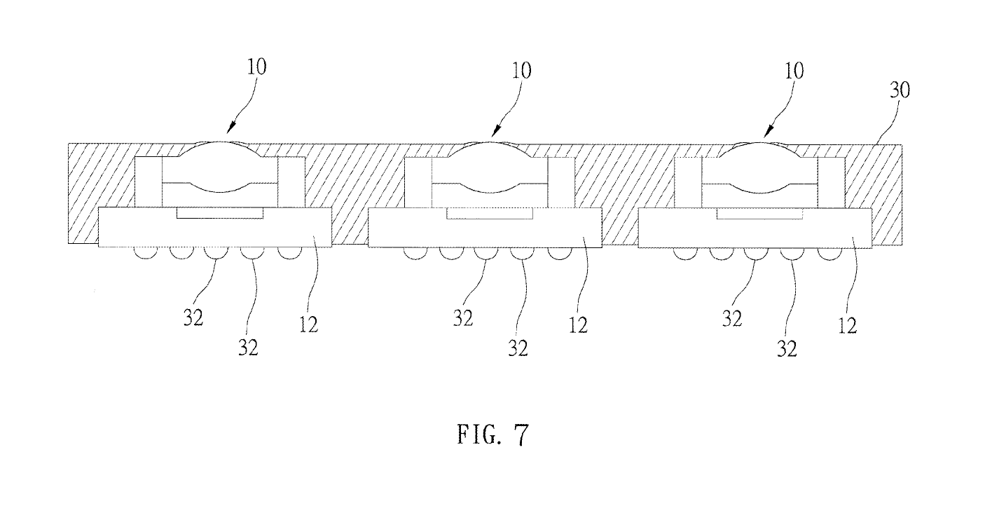

E. Providing solder bumps 32 on the bottoms of the substrates 12 of the lens members 10 to electrically connect to the conductor patterns respectively. As shown FIG. 7, ball plating is applied in the present step to make the substrates ball grid array (BGA) substrates, therefore, the conductor pattern may be electrically connected to another circuit through the solider balls 32.

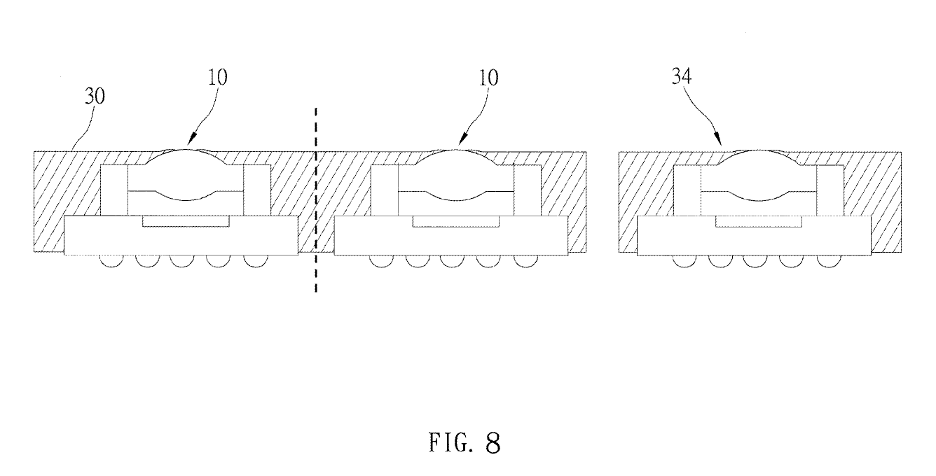

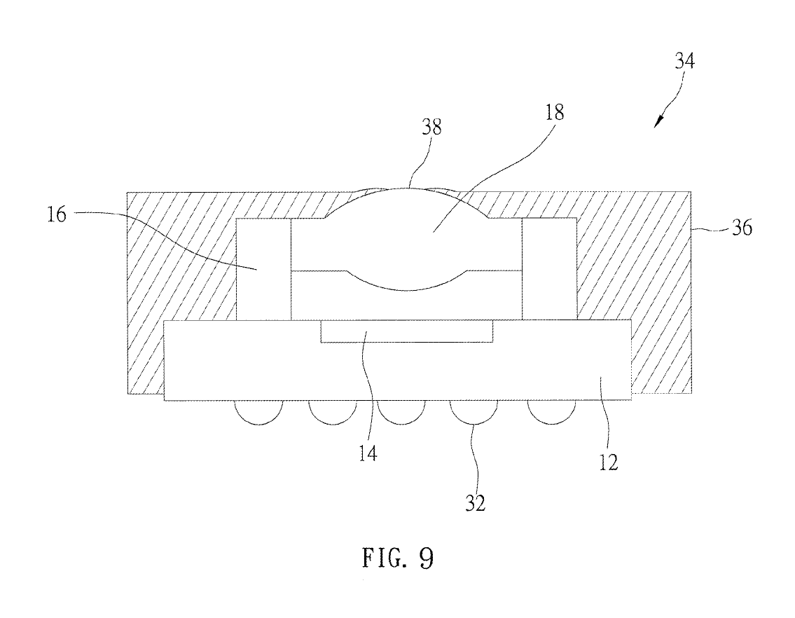

F. Cut the block, as shown in FIG. 8, to obtain a plurality of lens modules 34. As shown in FIG. 9, each lens module 34 includes a housing 36, which is formed by the housing material 30, and the lens member 10 embedded in the housing 36. The housing 36 has an opening 30, which is made by the contacting portions 22 of the first die 20, on a top to expose the lens 18. The opening 38 serves the function of aperture. In the present embodiment, the lens 18 has a portion extending out of the housing 36 through the opening 38. The housing 36 has a cavity therein which is exactly complementary to the lens member 10 to embed it therein without any gap therebetween.

The lens module 34 made by the method of the present invention has the following advantages:

1. The housing 36 firmly embeds the lens member 10 therein without any gap therebetween to make the lens module 34 a firm rigid unit, and therefore, the lens module 34 will has a strong structure.

2. The height of the lens module 34 is reduced.

3. Any kind of lens member may be applied in the same process of the method of the present invention.

4. The cost of manufacture is lower than the conventional method.

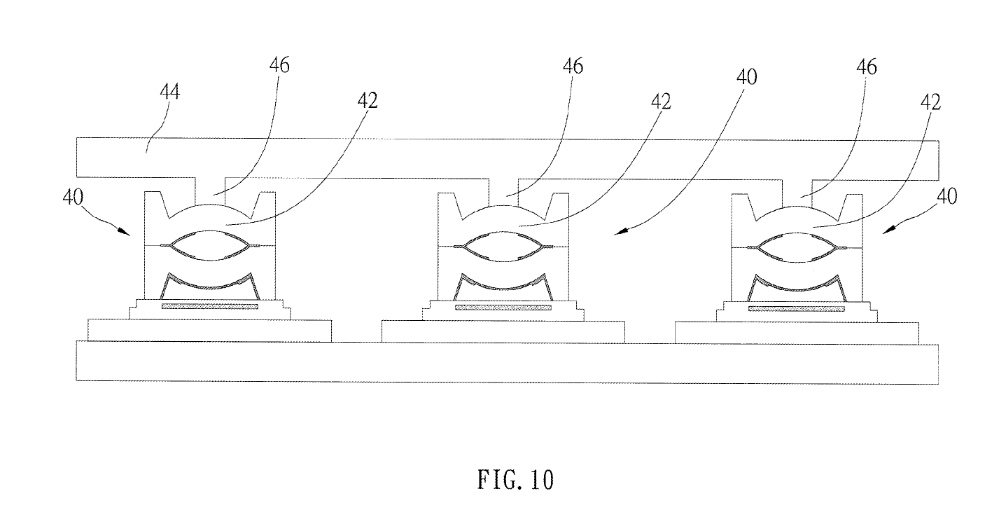

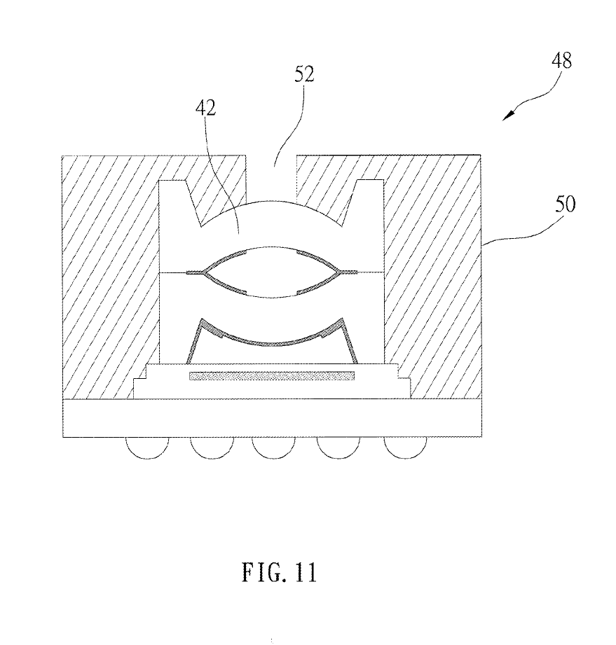

FIG. 10 shows a lens member 40 which the lens 42 is not at the highest place. To treat such lens member 40 by the method of the present invention, a second die 44 is provided with a plurality of posts 46 to be the contacting portions. Distal ends of the posts 46 will touch the lenses 42 when the second die 44 is flipped on the lens members 40. Except for the second die 44, the rest parts are the same as the first preferred embodiment. FIG. 11 shows a lens module 48 of the second preferred embodiment of the present invention, it is the same as the lens module 34 of the first preferred embodiment, except that the lens 42 is behind an opening 52 of a housing 50, and the lens 42 touches a rear end of the opening 52

The description above is a few preferred embodiments of the present invention and the equivalence of the present invention is still in the scope of claim construction of the present invention.

What is claimed is:

1. A method of making lens modules, comprising the steps of:
providing a plurality of lens members between a first die and a second die, wherein the lens member has a substrate having a conductor pattern, an image sensor provided on the substrate and electrically connected to the conductor pattern, a barrel mounted on the substrate, and a lens mounted in the barrel and above the image sensor; the first die has a plurality of positioning portions to respectively touch bottoms of the substrates of the lens members; the second die has a plurality of contacting portions to respectively touch the lenses; and a runner is formed between the lens members;
providing a housing material between the first die and the second die to fill the runner, and then curing the housing material, wherein the housing material embeds the lens members except the substrates touched by the first die and the lenses touched by the second die;
removing the first die and the second die to obtain a block; and
cutting the block to obtain a plurality of the lens module, wherein each of the lens module includes a housing formed by the housing material and the lens member in the housing.

2. The method as defined in claim 1, wherein the positioning portions of the first die are recesses on the first die, and the recesses are complementary to the substrates.

3. The method as defined in claim 1, wherein the contacting portions of the second die are recesses on the second die, and the recesses are complementary to the lenses.

4. The method as defined in claim 1, wherein the second die is flexible to be deformed by the lenses to form the contacting portions when the second die is put on the lens members and pressed.

5. The method as defined in claim 1, wherein the contacting portions of the second die are posts on the second die to respectively touch the lenses by distal ends thereof.

6. The method as defined in claim 1, further comprising the step of providing solder bumps on the bottoms of the substrates after the step of removing the first die and the second die.

7. The method as defined in claim 1, further comprising the step of providing solder balls on the bottoms of the substrates after the step of removing the first die and the second die.

8. The method as defined in claim 1, wherein the housing material is selected from the group consisting of epoxy, natural rubber, and thermosetting plastic.

9. A lens module, comprising:
a lens member including a substrate having a conductor pattern, an image sensor provided on the substrate and electrically connected to the conductor pattern, a barrel mounted on the substrate, and a lens mounted in the barrel and above the image sensor; and
a housing embedding the lens member, wherein the housing has an opening on a top thereof to expose at least a portion of the lens of the lens member; and the housing has a cavity exactly complementary to the lens member.

10. The lens module as defined in claim 9, wherein the portion of the lens extends out of the housing through the opening.

11. The lens module as defined in claim 1, wherein the lens is behind the opening of the housing, and touches a rear end of the opening.

12. The lens module as defined in claim 9, wherein the substrate has a portion not covered by the housing, on which solder bumps are provided to electrically connect to the conductor pattern.

13. The lens module as defined in claim 9, wherein the substrate has a portion not covered by the housing, on which solder balls are provided to electrically connect to the conductor pattern.
